(19) United States
(12) Patent Application Publication
(10) Pub. No.: US 2023/0317783 A1
(43) Pub. Date: Oct. 5, 2023

(54) LAYERED 2D SEMICONDUCTORS

(71) Applicant: Intel Corporation, Santa Clara, CA (US)

(72) Inventors: Kirby MAXEY, Hillsboro, OR (US); Carl H. NAYLOR, Portland, OR (US); Uygar E. AVCI, Portland, OR (US); Chelsey DOROW, Portland, OR (US); Kevin P. O'BRIEN, Portland, OR (US); Scott B. CLENDENNING, Portland, OR (US); Matthew V. METZ, Portland, OR (US); Chia-Ching LIN, Portland, OR (US); Sudarat LEE, Hillsboro, OR (US); Ashish Verma PENUMATCHA, Beaverton, OR (US)

(21) Appl. No.: 17/709,365

(22) Filed: Mar. 30, 2022

(51) Int. Cl. H01L 29/06; H01L 29/786; H01L 21/8234; H01L 29/66

(52) U.S. Cl. CPC H01L 29/0665; H01L 29/78696; H01L 29/66742; H01L 21/823412; H01L 29/78651

(57) ABSTRACT

Embodiments described herein may be related to forming nano ribbon transistors using layered 2D semiconductor channels. The layered 2D semiconductor channels may be created by forming a scaffold structure that has a first edge that extends from a silicon-based substrate, and a second edge opposite the first edge that is distal to the silicon based substrate. Alternating layers of 2D semiconductor material and a 3D semiconductor material may then be built on the second edge of the scaffold structure. In embodiments, the 3D semiconductor material may then be removed and a gate material deposited around at least a portion of the layers of 2D semiconductor material.

### FIELD

Embodiments of the present disclosure generally relate to the field of semiconductor packaging, and in particular to transistor structures that include 2D semiconductor layers.

### BACKGROUND

Continued growth in virtual machines, cloud computing, and portable devices will continue to increase the demand for high density transistors within chips and packages.

### BRIEF DESCRIPTION OF THE DRAWINGS

FIG. 1 shows a perspective view of a plurality of layers of a 2D semiconductor stacked on a plurality of scaffolding structures, in accordance with various embodiments.

FIG. 2 shows a perspective view of a nanoribbon transistor with a plurality of stacked 2D semiconductor channel layers that extend through a gate, in accordance with various embodiments.

FIGS. 3A-3H show a series of perspective views of stages in a manufacturing process for creating a plurality of layers of a 2D semiconductor stacked on a plurality of scaffolding structures, in accordance with various embodiments.

FIGS. 4A-4E show a series of perspective views of stages in a manufacturing process for creating a plurality of layers of a 2D semiconductor that extend through a gate, in accordance with various embodiments.

FIG. 5 shows an example of aspect ratio trapping (ART) techniques used to create scaffolding onto which layers of 2D semiconductor material may be formed, in accordance with various embodiments.

FIG. 6 illustrates an example process for manufacturing a package that includes a scaffolding with layers of a 2D semiconductor formed on the scaffolding, in accordance with various embodiments.

FIGS. 7A-7B schematically illustrate a top view of an example die in wafer form and in singulated form, and a cross section side view of a package assembly, in accordance with various embodiments.

FIG. 8 illustrates a computing device in accordance with one implementation of the invention.

FIG. 9 illustrates an interposer that includes one or more embodiments of the invention.

### DETAILED DESCRIPTION

Embodiments described herein may be related to apparatuses, processes, systems, and/or techniques directed to providing 2D semiconductor channels within transistors, and in particular to layered and/or stacked 2D semiconductor channels within gate structures of a transistor to form a nanoribbon structure. Embodiments described herein may be directed to creating 2D semiconductor channel layers by forming a scaffold structure that has a first edge that extends from a silicon-based substrate, and a second edge opposite the first edge that is distal to the silicon based substrate. Alternating layers of 2D semiconductor material and a 3D semiconductor material, such as but not limited to an oxide layer, a nitride, or other material compatible with precursors, may then be built on the second edge of the scaffold structure. In embodiments, the oxide layer may then be subsequently removed and a gate material deposited around at least a portion of the layers of 2D semiconductor material. In embodiments, the 2D semiconductor channel may be a single crystal structure that is grown on the scaffold structure or on the 3D semiconductor material.

In embodiments, transistors with 2D semiconductor channels as described herein may be used to scale device channel lengths below 10 nm. In embodiments, these 2D semiconductor channels may be grown as single crystals and regularly stacked in nanoribbon structures at pre-determined locations. In embodiments described below, ART templating techniques may be used on a silicon wafer, where the scaffold structure may be a sacrificial semiconductor that is vertically grown with few defects. In embodiments, minimizing defects may result in a precise edge of the scaffold structure onto which precisely defined and repeatable 2D semiconductor channels and 3D sacrificial semiconductor layer geometries may alternately be grown.

In embodiments, the scaffold structure and the 3D semiconductor layers may include, but are not limited to, group III-V material, group II-VI material, silicon germanium (SiGe), metal oxides, metal nitrides, and the like. As a result, these 3D semiconductor materials may be precisely grown, and subsequently precisely etched to leave a pre-determined pattern of 2D nanoribbons suitable for integration into stacked CMOS transistors. In embodiments using these techniques, the single crystal 2D semiconductors may all have a similar crystal structure.

In embodiments, a process for creating 2D nanoribbons as described above may also be referred to as using an additive technique, where the location of the 2D semiconductor nano ribbons are grown at locations predetermined by a single lithography step.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

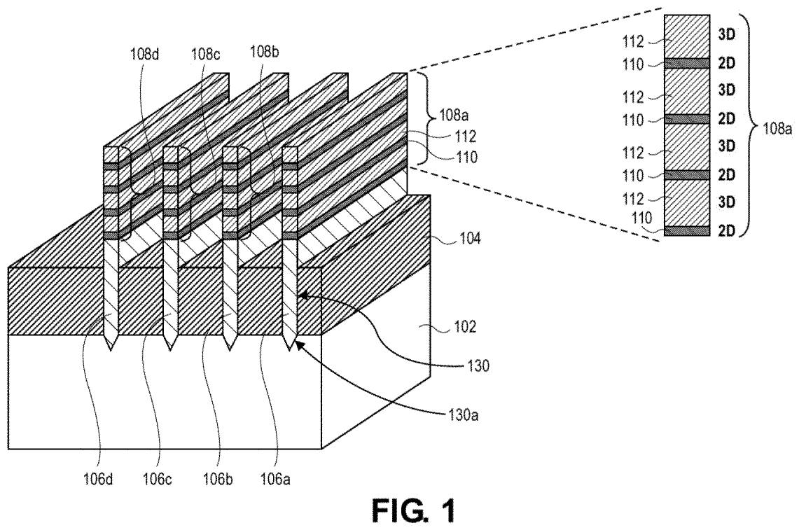

FIG. 1 shows a perspective view of a plurality of layers of a 2D semiconductor channel stacked on a plurality of scaffolding structures, in accordance with various embodiments. Substrate 102, which in embodiments may be silicon, may be used as a base for ART templating. In embodiments, the substrate 102 may be a wafer. A layer 104 may be placed on a side of the substrate 102. In embodiments, the layer 104 may include a field oxide. In embodiments, the layer 104 may be amorphous and thermally stable at temperatures up to approximately 1000° C., and/or chemically inert such that precursors use to grow scaffold structures 106a-106d grow only on substrate 102, and not the layer 104. In embodiments, the field oxide may include SiO₂. In embodiments, a thickness of the layer 104 may be chosen to support low defect growth of scaffold structures 106a-106d grown within trenches as described further below.

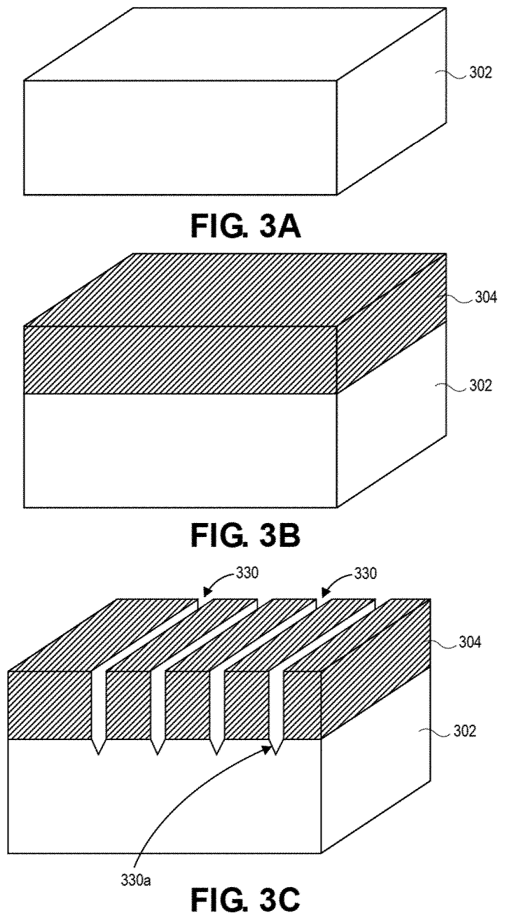

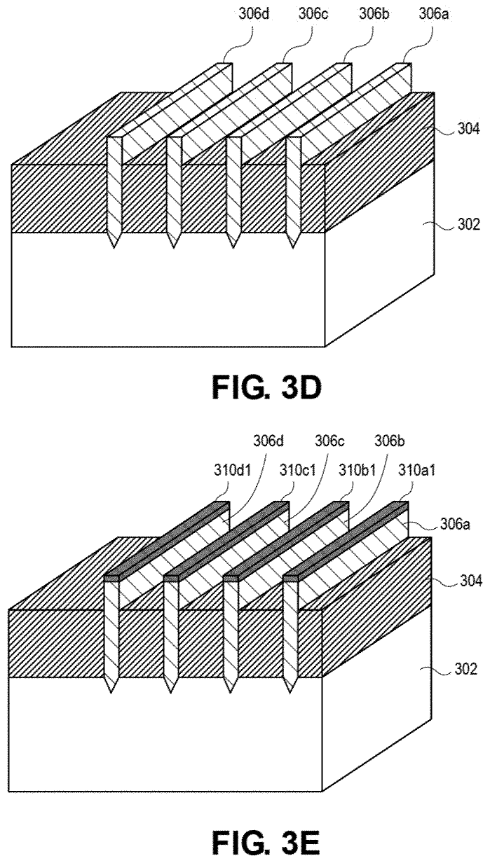

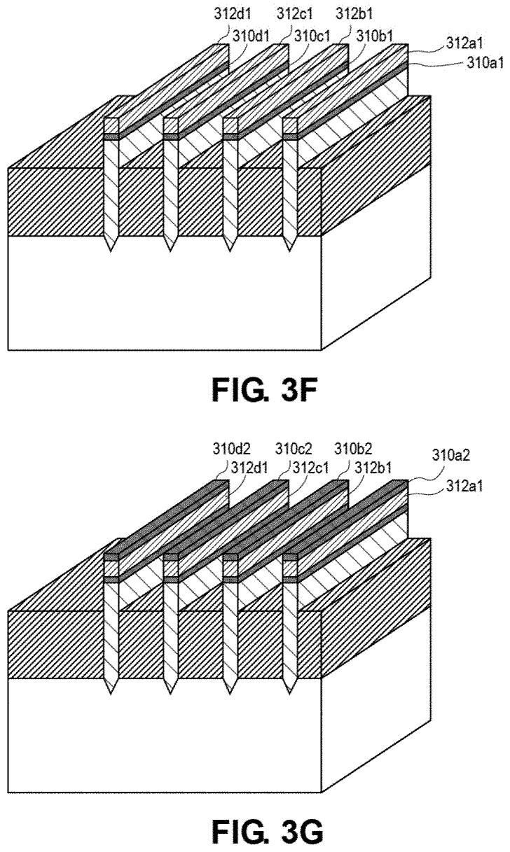

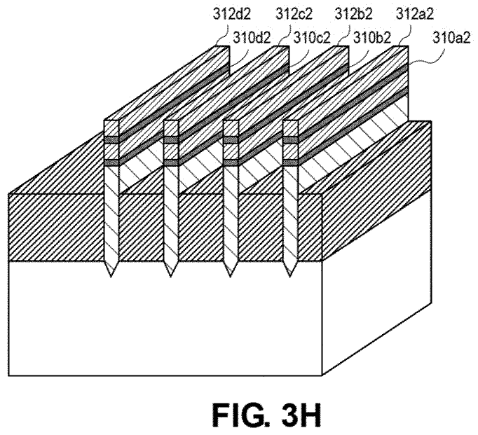

In embodiments, as discussed further below with respect to FIGS. 3A-3H, trenches may be formed through the layer 104. In embodiments, the layer 104 may be patterned, and then a chemical etch process used to create the trenches such as trench 130. In embodiments, the trenches may be formed through an etching process. In embodiments, a dry etch may be used followed by a wet etch to expose (111) facets. In embodiments, a triangular divot 130a may be formed. The trenches are then used to form a plurality of scaffolds 106a-106d. In embodiments, the plurality of scaffolds 106a-106d may be grown vertically from the silicon within substrate 102 with few defects.

Once the scaffolds 106a-106d are in place, layers 108a-108d of 2D material may be grown, respectively, on top of the scaffolds 106a-106d. The layers 108a-108d may include interleaving layers of a 2D semiconductor material 110 and a 3D material 112.

In embodiments, the 3D material included in the plurality of scaffolds 106a-106d, or as part of 3D layers 112, may include, but are not limited to, group III-V material, group II-VI material, and/or SiGe. Other materials including group III-nitride materials such as aluminum nitride (AlN) or gallium nitride (GaN) may be used due to their commensurate crystal structure with transition metal dichalcogenides (TMD) during the 2D semiconductor formation process for 2D layers 110. Other materials may also be used, such as group III-V (e.g. GaAs) or group II-VI (e.g. ZnTe) materials. The scaffolds 106a-106d do not have to be the same material as that used to grow from the Si substrate. For example, AlN could be used to grow through the ART patterning, with subsequent scaffolding consisting of TMD/ALD oxide laminates

In embodiments, the 2D semiconductor material 110 may include a crystal 2D semiconductor, and embodiments may be a single layer crystal 2D semiconductor. In embodiments, the 2D semiconductor material 100 may include but is not limited to MoS₂, MoSe₂, WS₂, ToTe₂, In₂Se₃. In embodiments, a defining feature of the 2D materials may be there layered structure, with typical chemical bonding in-plane, but very weak van der Waals bonding through the basal plane. This allows 2D materials to be grown extremely thin, for example as a single monolayer) with few defects on incommensurate substrates. The crystal 2D semiconductor may be grown using an epitaxial synthesis processes such as molecular beam epitaxy or metallo-organic chemical vapor deposition. In embodiments, the 2D semiconductor material 110 may subsequently become the 2D channel layers in a nanoribbon transistor.

In embodiments, the 3D material 112, which may also be referred to as a sacrificial semiconductor material, may also be grown on the plurality of scaffolds 106a-106d and/or the 2D semiconductor material 110. In embodiments, the 3D material 112 may be the same or similar to the material used in the plurality of scaffolds 106a-106d. In embodiments, as discussed further below with respect to FIGS. 3A-3H, the interleaving layers of the 2D semiconductor material 110 and the 3D material 112 may be built up by growing each layer 110, 112 progressively on each other. In embodiments, the 2D semiconductor material 110 and 3D material 112 may be grown within an epitaxy chamber.

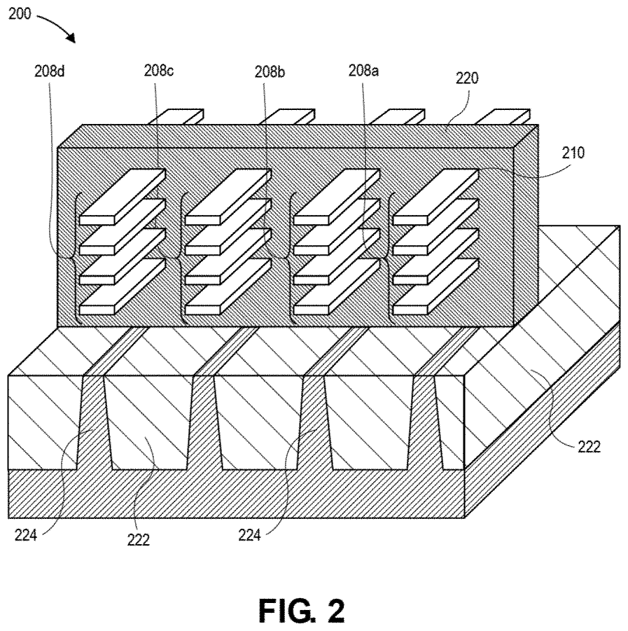

FIG. 2 shows a perspective view of a nanoribbon transistor with a plurality of stacked 2D semiconductor channel layers that extend through a gate, in accordance with various embodiments. A transistor structure 200 includes a gate 220 through which a plurality of 2D semiconductor layers 208a-208d, which may be similar to the 2D semiconductor material 110 of the layers 108a-108d of FIG. 1. In embodiments, the gate 220 may be on a substrate 222, with a different type of substrate material 224 underneath the 2D semiconductor layers 208a-208d.

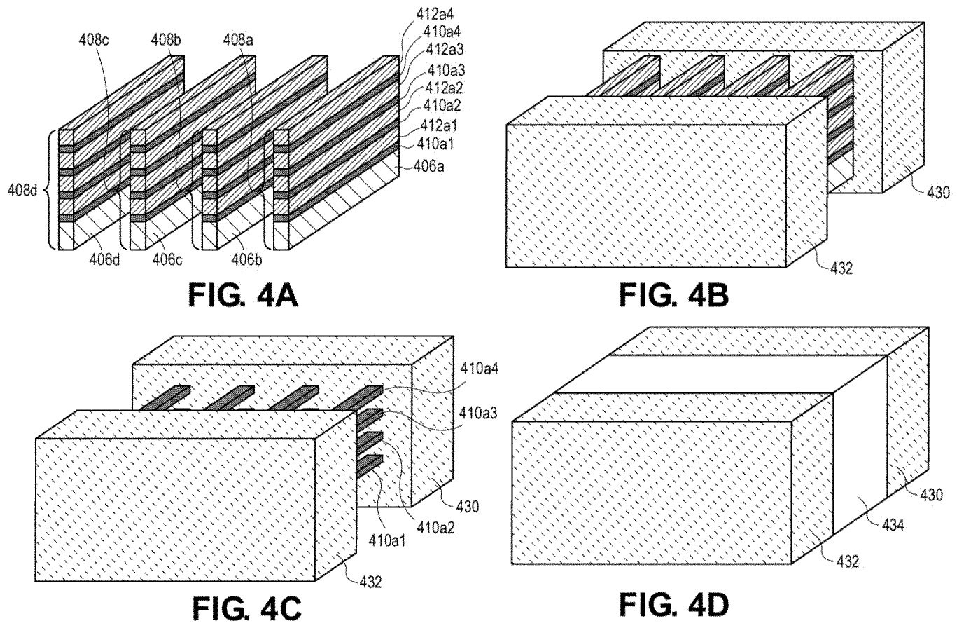

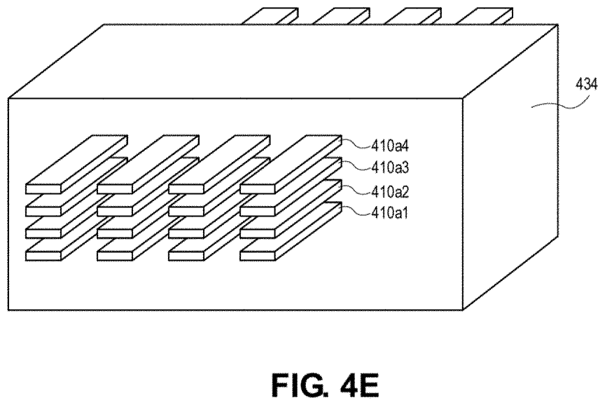

In embodiments, the 2D semiconductor layers 208a-208d may be formed by removing the 3D material 112 and the scaffold 106a-106d of FIG. 1, leaving 2D semiconductor layers 210, which may be similar to 2D semiconductor layers 110 of FIG. 1. A portion of the 2D semiconductor layers 208a-208d are enclosed with a gate material, such as a high-k metallic gate material, to form gate 220, which may also be referred to as a gate stack. Embodiments of this are described in detail with respect to FIGS. 4A-4E below.

FIGS. 3A-3H show a series of perspective views of stages in a manufacturing process for creating a plurality of layers of a 2D semiconductor stacked on a plurality of scaffolding structures, in accordance with various embodiments. FIG. 3A shows a stage in a manufacturing process that includes providing a substrate 302 that may include silicon, sapphire, or any other material that may be grown as an ingot, and may be similar to substrate 102 of FIG. 1.

FIG. 3B shows a stage in the manufacturing process where a layer 304, which may be similar to layer 104 of FIG. 1, may be placed on the substrate 302. In embodiments, the layer 304 may include a field oxide or a field insulator.

FIG. 3C shows a stage in the manufacturing process where trenches 330, which may be similar to trenches 130 of FIG. 1, are created through the layer 304, and into a portion of the substrate 302. In embodiments, the trenches 330 may be created by first patterning the top surface of the layer 304, and then subsequently applying an etching process to create the trenches 330. In embodiments, the trenches 330 are shown as planar, but may have any shape, including a serpentine shape or a ribbon shape (not shown) depending upon the desired resulting geometry of the 2D semiconductor layers 110 of FIG. 1.

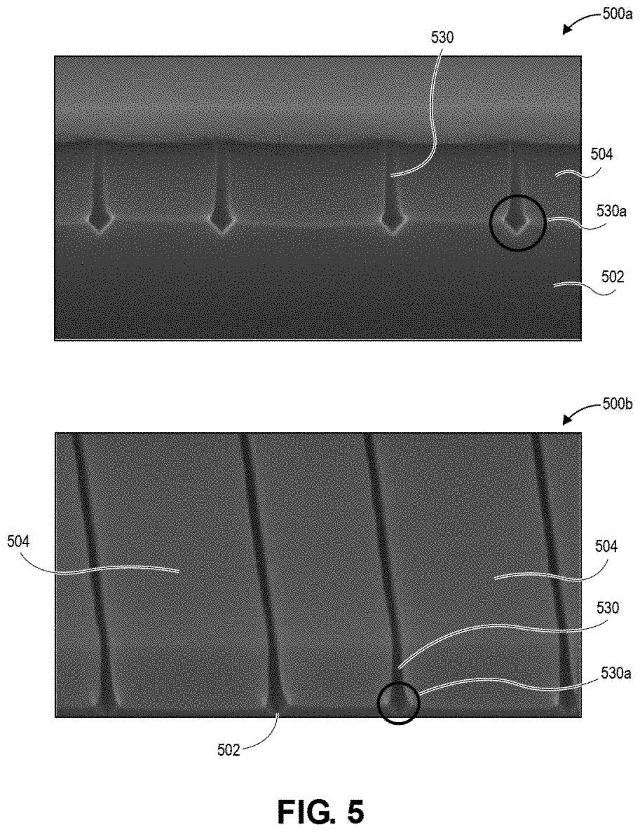

In embodiments, portions of this process may be a part of the ART process, and portions of the substrate 302 and/or the layer 304 may be referred to as an ART wafer. A representation of an ART wafer is described below with respect to FIG. 5. In embodiments, the silicon in the substrate 302 may be a (100) silicon wafer. When the etching process is applied, the {111} planes etch more slowly once the oxide in the layer 304 is etched through, resulting in a characteristic triangular divot 330a, that may be similar to triangular divot 130a of FIG. 1, in the substrate 302.

FIG. 3D shows a stage in the manufacturing process where scaffolding 306a-306d, which may be similar to scaffolding 106a-106d of FIG. 1, is formed. In embodiments, scaffolding 306a-306d, which may be referred to as a sacrificial material, may be semiconductor material that is grown on the silicon of the substrate 302, which grows up through the trenches 330. In embodiments, the scaffolding 306a-306d may selectively grow only on the substrate 302, and not on the layer 304.

As a result of this process, threading defect density of the scaffolding 306a-306d may be substantially reduced, resulting in a greater uniformity in a top edge of the scaffolding 306a-306d. As a result, the sides of each of the scaffolds 306a-306d are substantially parallel.

FIG. 3E shows a stage in the manufacturing process where 2D semiconductor layers 310a1-310d1, respectively, are placed on scaffolding 306a-306d. In embodiments, the 2D semiconductor layers 310a1-310d1 may be grown selectively on the scaffolding 306a-306d, for example, within an epitaxial chamber. In embodiments, the 2D semiconductor layers 310a1-310d1 will grow only on the top surfaces of 306a-306d.

FIG. 3F shows a stage in the manufacturing process where 3D semiconductor layers 312a1-312d1 are placed, respectively, on 2D semiconductor layers 310a1-310d1. In embodiments, a thickness of the 3D semiconductor layer 312a1 may be chosen based upon a desired separation between the vertical stacks of various 2D semiconductor layers that are subsequently formed during this process. In embodiments, a material chosen for 3D semiconductor layers 312a1-312d1 is able to be selectively etched without damaging 2D semiconductor layers 310a1-310d1 or layer 304 during selective etching. A thickness is chosen to allow for subsequent deposition of a high-k dielectric and metal gate. Note that the process described with respect to FIG. 3F may be performed within a same epitaxial chamber as the process described with respect to FIG. 3E. In embodiments, fewer defects in scaffolding 306a-306d means fewer defects in 2D semiconductor layers 310a1-310d1, because 2D semiconductor layers 310a1-310d1 use scaffolding 306a-306d as a template for crystal structure.

FIG. 3G shows a stage in the manufacturing process where another group of 2D semiconductor layers 310a2-310d2 are formed, respectively, upon the 3D semiconductor layer layers 312a1-312d1. At this stage, there are two 2D semiconductor layers 310a1-310d1 and 310a2-310d2 that are stacked, respectively, on each other.

FIG. 3H shows a stage in the manufacturing process where 3D semiconductor layers 312a2-312d2 are placed, respectively, on 2D semiconductor layers 310a2-310d2. As can be appreciated, the processes described with respect to FIG. 3G and FIG. 3H may be repeated to achieve any number of levels of 2D semiconductor layers 310.

It should be noted that during the 2D semiconductor layer formation process, a crystal orientation of each layer of the 2D semiconductor layers 310a1, 310a2 may have the same crystallographic orientation.

FIGS. 4A-4E show a series of perspective views of stages in a manufacturing process for creating a plurality of layers of a 2D semiconductor that extend through a gate, in accordance with various embodiments. FIG. 4A shows a stage in the manufacturing process where layers 408a-408d are formed, respectively, on scaffolding 406a-406d. Layers 408a-408d may be similar to layers 108a-108d, and scaffolding 406a-406d may be similar to scaffolding 106a-106d of FIG. 1. Layer 408a shows an example of four 2D semiconductor material layers 410a1-410a4 that are separated by four 3D semiconductor material layers 412a1-412a4. It should be noted that the number of layers shown is four; however, there may be an arbitrary number of layers.

FIG. 4B shows a stage in the manufacturing process where a temporary fill 430, 432 may be placed around a portion of the layers 408a-408d. In embodiments, the temporary fill 430, 432 may be a molding or some other material that may be used to secure the positioning of the layers 408-408d during further processing. In embodiments, the temporary fill 430 may include silicon nitride.

FIG. 4C shows a stage in the manufacturing process where the non-2D semiconductor material is removed. In embodiments, this may involve applying a wet etch process. For example, as shown the 3D semiconductor material layers 412a1-412a4 are etched away, as well as is the scaffold 406a-406d. In embodiments, a wet etch or a vapor phase etch may be used.

Note that in embodiments, temporary fill 430, 432 may be very thin and the 2D semiconductor material layers 410a1-410a4 may poke out of the face of 430, 432. In embodiments, if the material of temporary fill 430, 432, they may be kept and used a spacer material between gate and source/drain contacts.

FIG. 4D shows a stage in the manufacturing process where a gate material 434 is applied to surround the 2D semiconductor layers, such as 2D semiconductor layers 410a1-410a4. In embodiments, the gate material may be similar to the gate material used with respect to gate 220 of FIG. 2. In embodiments, the gate material may be a high-k gate material, which may include, but is not limited to, hafnium oxide, zirconium oxide, aluminum oxide, and silicon oxide.

FIG. 4E shows a stage in the manufacturing process where the temporary fill 430, 432 of FIG. 4B is removed. As a result, a plurality of stacked nano-ribbons, such as stacked 2D semiconductor layers 410a1-410a4, extend through the gate 434, and also extend on either side of the gate as shown.

FIG. 5 shows an example of ART techniques used to create scaffolding onto which layers of 2D semiconductor material may be formed, in accordance with various embodiments. Diagram 500a shows a side view of an ART wafer that includes a silicon substrate 502, which may be similar to substrate 102 of FIG. 1. A layer 504 on top of the silicon substrate 502 includes a plurality of trenches 530 that extend through the layer 504 and into the top of the silicon substrate 502. In embodiments as discussed above, creating such trenches 530 may be the result of the patterning and etching process. As a result of the etching process, a triangular divot 530a, which may be similar to triangular divot 130a of FIG. 1, may be formed. Diagram 500b shows a perspective view of the ART wafer that shows silicon substrate 502, the layer 504, trench 530, and a portion of the triangular divot 530a. Note that in embodiments a length of the trenches 530 may be substantially greater than a height or a width of the trenches.

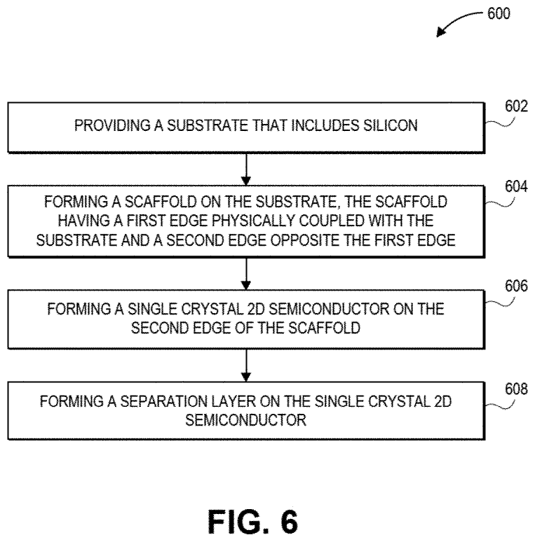

FIG. 6 illustrates an example process for manufacturing a package that includes a scaffolding with layers of a 2D semiconductor formed on the scaffolding, in accordance with various embodiments. Process 600 may be implemented using the techniques and/or embodiments described herein, and in particular with respect to FIGS. 1-5.

At block 602, the process may include providing a substrate that includes silicon.

At block 604, the process may further include forming a scaffold on the substrate, the scaffold having a first edge physically coupled with the substrate and a second edge opposite the first edge.

At block 606, the process may further include forming a single crystal 2D semiconductor on the second edge of the scaffold.

At block 608, the process may further include forming a separation layer on the single crystal 2D semiconductor. It should be appreciated that after block 608, the process may return to block 606.

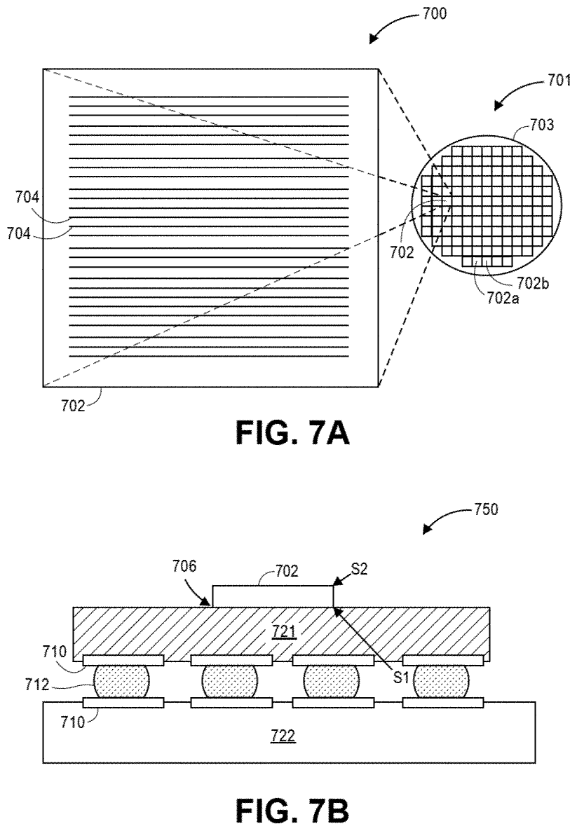

FIGS. 7A-7B schematically illustrate a top view of an example die in wafer form and in singulated form, and a cross section side view of a package assembly, in accordance with various embodiments. FIG. 7A schematically illustrates a top view of an example die 702 in a wafer form 701 and in a singulated form 700, in accordance with some embodiments. In some embodiments, die 702 may be one of a plurality of dies, e.g., dies 702, 702a, 702b, of a wafer 703 comprising semiconductor material, e.g., silicon or other suitable material. The plurality of dies, e.g., dies 702, 702a, 702b, may be formed on a surface of wafer 703. Each of the dies 702, 702a, 702b, may be a repeating unit of a semiconductor product that includes devices as described herein. For example, die 702 may include circuitry having elements such as capacitors and/or inductors 704 (e.g., fin structures, nanowires, and the like) that provide a channel pathway for mobile charge carriers in transistor devices. Although one or more capacitors and/or inductors 704 are depicted in rows that traverse a substantial portion of die 702, it is to be understood that one or more capacitors and/or inductors 704 may be configured in any of a wide variety of other suitable arrangements on die 702 in other embodiments.

After a fabrication process of the device embodied in the dies is complete, wafer 703 may undergo a singulation process in which each of dies, e.g., die 702, is separated from one another to provide discrete “chips” of the semiconductor product. Wafer 703 may be any of a variety of sizes. In some embodiments, wafer 703 has a diameter ranging from about 25.4 mm to about 450 mm. Wafer 703 may include other sizes and/or other shapes in other embodiments. According to various embodiments, the one or more capacitors and/or inductors 704 may be disposed on a semiconductor substrate in wafer form 701 or singulated form 700. One or more capacitors and/or inductors 704 described herein may be incorporated in die 702 for logic, memory, or combinations thereof. In some embodiments, one or more capacitors and/or inductors 704 may be part of a system-on-chip (SoC) assembly.

FIG. 7B schematically illustrates a cross-section side view of an integrated circuit (IC) assembly 750, in accordance with some embodiments. In some embodiments, IC assembly 750 may include one or more dies, e.g., die 702, electrically or physically coupled with a package substrate 721. Die 702 may include one or more capacitors and/or inductors 704 as described herein in FIG. 7A. In some embodiments, package substrate 721 may be electrically coupled with a circuit board 722 as is well known to a person of ordinary skill in the art. Die 702 may represent a discrete product made from a semiconductor material (e.g., silicon) using semiconductor fabrication techniques such as thin film deposition, lithography, etching, and the like. In some embodiments, die 702 may be, include, or be a part of a processor, memory, SoC or ASIC in some embodiments.

Die 702 can be attached to package substrate 721 according to a wide variety of suitable configurations including, for example, being directly coupled with package substrate 721 in a flip-chip configuration, as depicted. In the flip-chip configuration, an active side 51 of die 702 including circuitry is attached to a surface of package substrate 721 using hybrid bonding structures as described herein that may also electrically couple die 702 with package substrate 721. Active side 51 of die 702 may include multi-threshold voltage transistor devices as described herein. An inactive side S2 of die 702 may be disposed opposite to active side 51.

In some embodiments, package substrate 721 is an epoxy-based laminate substrate having a core and/or build-up layers such as, for example, an Ajinomoto Build-up Film (ABF) substrate. Package substrate 721 may include other suitable types of substrates in other embodiments including, for example, substrates formed from glass, ceramic, or semiconductor materials.

Package substrate 721 may include electrical routing features configured to route electrical signals to or from die 702. The electrical routing features may include pads or traces (not shown) disposed on one or more surfaces of package substrate 721 and/or internal routing features (not shown) such as trenches, vias, or other interconnect structures to route electrical signals through package substrate 721. In some embodiments, package substrate 721 may include electrical routing features such as pads (not shown) configured to receive the respective die-level interconnect structures 706 of die 702.

Circuit board 722 may be a printed circuit board (PCB) comprising an electrically insulative material such as an epoxy laminate. Circuit board 722 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Interconnect structures such as traces, trenches, vias may be formed through the electrically insulating layers to route the electrical signals of die 702 through circuit board 722. Circuit board 722 may comprise other suitable materials in other embodiments. In some embodiments, circuit board 722 is a motherboard as is well known to a person of ordinary skill in the art.

Package-level interconnects such as, for example, solder balls 712 may be coupled to one or more pads 710 on package substrate 721 and/or on circuit board 722 to form corresponding solder joints that are configured to further route the electrical signals between package substrate 721 and circuit board 722. Pads 710 may comprise any suitable electrically conductive material such as metal including, for example, nickel (Ni), palladium (Pd), gold (Au), silver (Ag), copper (Cu), and combinations thereof. Other suitable techniques to physically and/or electrically couple package substrate 721 with circuit board 722 may be used in other embodiments.

IC assembly 750 may include a wide variety of other suitable configurations in other embodiments including, for example, suitable combinations of flip-chip and/or wire-bonding configurations, interposers, multi-chip package configurations including system-in-package (SiP), and/or package-on-package (PoP) configurations. Other suitable techniques to route electrical signals between die 702 and other components of IC assembly 750 may be used in some embodiments.

A person of ordinary skill in the art should recognize that any known semiconductor device fabricated using any known semiconductor process that may benefit from the principles described herein.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

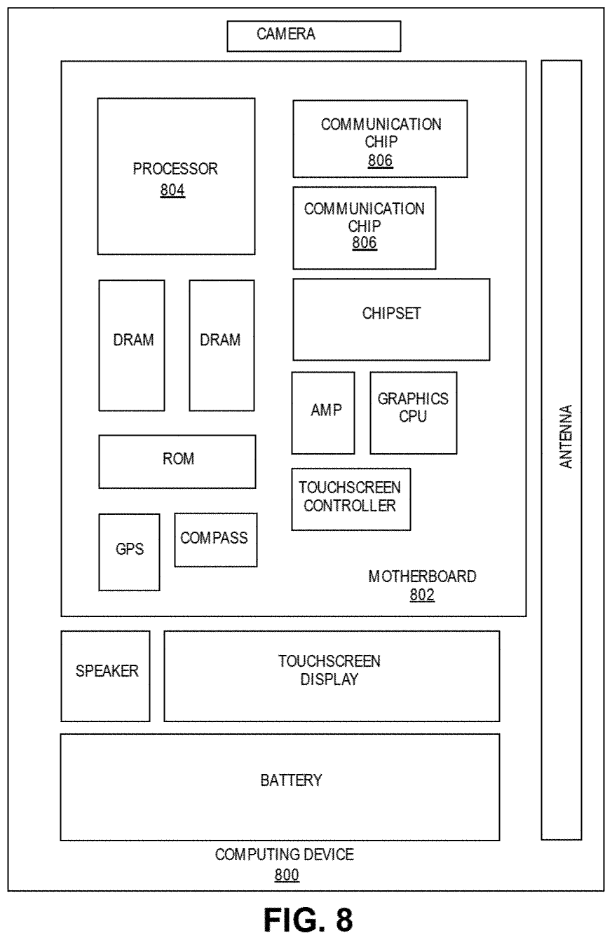

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip includes one or more devices, such as MOS-FET transistors built in accordance with implementations of the invention.

In further implementations, another component housed within the computing device 800 may contain an integrated circuit die that includes one or more devices, such as MOS-FET transistors built in accordance with implementations of the invention.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

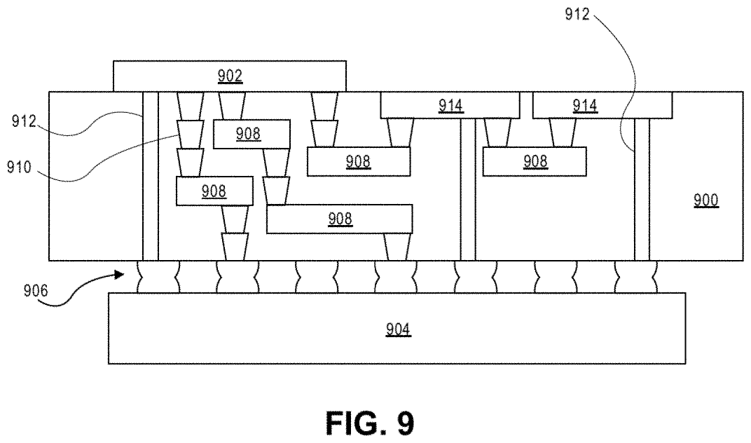

FIG. 9 illustrates an interposer 900 that includes one or more embodiments of the invention. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902/904 are attached to opposing sides of the interposer 900. In other embodiments, the first and second substrates 902/904 are attached to the same side of the interposer 900. And in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer 900 may be formed of alternate rigid or flexible materials that may include the same materials described above for use in a semiconductor substrate, such as silicon, germanium, and other group III-V and group IV materials.

The interposer 900 may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the invention, apparatuses or processes disclosed herein may be used in the fabrication of interposer 900.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is an apparatus comprising: a substrate that includes silicon; a layer with a first side and a second side opposite the first side, the first side of the layer on a side of the substrate; a scaffold extending from a portion of the substrate proximate to the side of the substrate through at least a portion of the layer, wherein a first edge of the scaffold is adjacent to a portion of the substrate and wherein a second edge of the scaffold opposite the first edge of the scaffold is distal to the substrate; and a semiconductor layer on the second edge of the scaffold.

Example 2 may include the apparatus of example 1, or of any other example or embodiment herein, wherein the semiconductor layer is a single crystal 2D semiconductor.

Example 3 may include the apparatus of example 2, or of any other example or embodiment herein, wherein the semiconductor layer is grown on the second edge of the scaffold.

Example 4 may include the apparatus of example 1, or of any other example or embodiment herein, wherein the scaffold includes a semiconductor material.

Example 5 may include the apparatus for example 1, or of any other example or embodiment herein, wherein the scaffold forms a plane that is substantially perpendicular to a plane of the side of the substrate.

Example 6 may include the apparatus of example 1, or of any other example or embodiment herein, wherein the semiconductor layer is a first semiconductor layer; and further comprising: a separation layer on the first semiconductor layer; and a second semiconductor layer on the separation layer.

Example 7 may include the apparatus of example 6, or of any other example or embodiment herein, wherein the separation layer is grown on the first semiconductor layer.

Example 8 may include the apparatus of example 6, or of any other example or embodiment herein, wherein the first semiconductor layer and the second semiconductor layer include a single crystal 2D semiconductor.

Example 9 may include the apparatus of example 8, or of any other example or embodiment herein, wherein the first semiconductor layer and the second semiconductor layer have a same crystal orientation.

Example 10 may include the apparatus of example 6, or of any other example or embodiment herein, wherein the separation layer is a first separation layer; and further comprising: a second separation layer on the second semiconductor layer; and a third semiconductor layer on the second separation layer, wherein the third semiconductor layer is a single crystal 2D semiconductor.

Example 11 may include the apparatus of example 1, or of any other example or embodiment herein, wherein the scaffold is a first scaffold; and further comprising: a second scaffold extending from a portion of the substrate proximate to the side of the substrate through at least a portion of the layer, wherein a first edge of the scaffold is adjacent to a portion of the substrate and wherein a second edge of the scaffold opposite the first edge of the scaffold is distal to the substrate; and a semiconductor layer on the second edge of the second scaffold.

Example 12 may include the apparatus of example 11, or of any other example or embodiment herein, wherein the first scaffold and the second scaffold are substantially parallel with each other.

Example 13 may include the apparatus of example 1, or of any other example or embodiment herein, wherein the scaffold is grown from the substrate.

Example 14 may include the apparatus of example 1, or of any other example or embodiment herein, wherein the layer on the substrate includes silicon and oxygen.

Example 15 is a transistor structure comprising: a gate structure that includes a gate; and a layer of semiconductor material extending through a material of the gate, the layer of semiconductor material including a single crystal 2D semiconductor.

Example 16 may include the transistor structure of example 15, or of any other example or embodiment herein, wherein the layer of semiconductor material includes a plurality of layers of semiconductor material that are substantially parallel to each other and substantially overlap each other, wherein each of the plurality of layers is separated by a portion of the material of the gate.

Example 17 may include the transistor structure of example 16, or of any other example or embodiment herein, wherein each of the plurality of layers have a same crystal orientation.

Example 18 may include the transistor structure of example 16, or of any other example or embodiment herein, wherein the plurality of layers is a first plurality of layers of semiconductor material; and further comprising: a second plurality of layers of semiconductor material that are substantially parallel to each other and substantially overlap each other, wherein each of the second plurality of layers is separated by a portion of the material of the gate.

Example 19 may include the transistor structure of example 18, or of any other example or embodiment herein, wherein the first plurality of layers and the second plurality of layers are adjacent to each other.

Example 20 may include the transistor structure of example 18, or of any other example or embodiment herein, wherein the each of the first plurality of layers are, respectively, in a same plane as the each of the second plurality of layers.

Example 21 may include the transistor structure of example 15, or of any other example or embodiment herein, wherein the layer of semiconductor material includes a channel of a transistor.

Example 22 is a method comprising: providing a substrate that includes silicon; forming a scaffold on the substrate, the scaffold having a first edge physically coupled with the substrate and a second edge opposite the first edge; forming a single crystal 2D semiconductor on the second edge of the scaffold; and forming a separation layer on the single crystal 2D semiconductor.

Example 23 may include the method of example 22, or of any other example or embodiment herein, wherein the single crystal 2D semiconductor is a first single crystal 2D semiconductor, and wherein the separation layer is a first separation layer; and further comprising: forming a second single crystal 2D semiconductor on the first separation layer; and forming a second separation layer on the second single crystal 2D semiconductor.

Example 24 may include the method of example 22, or of any other example or embodiment herein, wherein forming a scaffold on the substrate further includes: forming a layer on the substrate, the layer having a first side on the substrate and a second side of the layer opposite the first side; etching a trench from the second side of the layer through the first side of the layer and into a portion of the substrate; and forming the scaffold within the etched trench.

Example 25 may include the method of example 24, or of any other example or embodiment herein, wherein forming the scaffold within the etched trench further includes growing the scaffold within the etched trench from a surface of the substrate.

What is claimed is:

1. An apparatus comprising:
a substrate that includes silicon;
a layer with a first side and a second side opposite the first side, the first side of the layer on a side of the substrate;
a scaffold extending from a portion of the substrate proximate to the side of the substrate through at least a portion of the layer, wherein a first edge of the scaffold is adjacent to a portion of the substrate and wherein a second edge of the scaffold opposite the first edge of the scaffold is distal to the substrate; and
a semiconductor layer on the second edge of the scaffold.

2. The apparatus of claim 1, wherein the semiconductor layer is a single crystal 2D semiconductor.

3. The apparatus of claim 2, wherein the semiconductor layer is grown on the second edge of the scaffold.

4. The apparatus of claim 1, wherein the scaffold includes a semiconductor material.

5. The apparatus of claim 1, wherein the scaffold forms a plane that is substantially perpendicular to a plane of the side of the substrate.

6. The apparatus of claim 1, wherein the semiconductor layer is a first semiconductor layer; and further comprising:
a separation layer on the first semiconductor layer; and
a second semiconductor layer on the separation layer.

7. The apparatus of claim 6, wherein the separation layer is grown on the first semiconductor layer.

8. The apparatus of claim 6, wherein the first semiconductor layer and the second semiconductor layer include a single crystal 2D semiconductor.

9. The apparatus of claim 8, wherein the first semiconductor layer and the second semiconductor layer have a same crystal orientation.

10. The apparatus of claim 6, wherein the separation layer is a first separation layer; and further comprising:
a second separation layer on the second semiconductor layer; and
a third semiconductor layer on the second separation layer, wherein the third semiconductor layer is a single crystal 2D semiconductor.

11. The apparatus of claim 1, wherein the scaffold is a first scaffold; and further comprising:
a second scaffold extending from a portion of the substrate proximate to the side of the substrate through at least a portion of the layer, wherein a first edge of the scaffold is adjacent to a portion of the substrate and wherein a second edge of the scaffold opposite the first edge of the scaffold is distal to the substrate; and
a semiconductor layer on the second edge of the second scaffold.

12. The apparatus of claim 11, wherein the first scaffold and the second scaffold are substantially parallel with each other.

13. The apparatus of claim 1, wherein the scaffold is grown from the substrate.

14. The apparatus of claim 1, wherein the layer on the substrate includes silicon and oxygen.

15. A transistor structure comprising:
a gate structure that includes a gate; and
a layer of semiconductor material extending through a material of the gate, the layer of semiconductor material including a single crystal 2D semiconductor.

16. The transistor structure of claim 15, wherein the layer of semiconductor material includes a plurality of layers of semiconductor material that are substantially parallel to each other and substantially overlap each other, wherein each of the plurality of layers is separated by a portion of the material of the gate.

17. The transistor structure of claim 16, wherein each of the plurality of layers have a same crystal orientation.

18. The transistor structure of claim 16, wherein the plurality of layers is a first plurality of layers of semiconductor material; and further comprising:
a second plurality of layers of semiconductor material that are substantially parallel to each other and substantially overlap each other, wherein each of the second plurality of layers is separated by a portion of the material of the gate.

19. The transistor structure of claim 18, wherein the first plurality of layers and the second plurality of layers are adjacent to each other.

20. The transistor structure of claim 18, wherein the each of the first plurality of layers are, respectively, in a same plane as the each of the second plurality of layers.

21. The transistor structure of claim 15, wherein the layer of semiconductor material includes a channel of a transistor.

22. A method comprising:
providing a substrate that includes silicon;
forming a scaffold on the substrate, the scaffold having a first edge physically coupled with the substrate and a second edge opposite the first edge;
forming a single crystal 2D semiconductor on the second edge of the scaffold; and
forming a separation layer on the single crystal 2D semiconductor.

23. The method of claim 22, wherein the single crystal 2D semiconductor is a first single crystal 2D semiconductor, and wherein the separation layer is a first separation layer; and further comprising:
forming a second single crystal 2D semiconductor on the first separation layer; and
forming a second separation layer on the second single crystal 2D semiconductor.

24. The method of claim 22, wherein forming a scaffold on the substrate further includes:
forming a layer on the substrate, the layer having a first side on the substrate and a second side of the layer opposite the first side;
etching a trench from the second side of the layer through the first side of the layer and into a portion of the substrate; and
forming the scaffold within the etched trench.

25. The method of claim 24, wherein forming the scaffold within the etched trench further includes growing the scaffold within the etched trench from a surface of the substrate.
